(19) United States
(12) Patent Application Publication
(10) Pub. No.: US 2026/0366903 A1
(43) Pub. Date: Nov. 19, 2026

(54) FLOWMETER VERIFICATION ON A MAGNETIC FLOWMETER

(71) Applicant: Micro Motion, Inc., Boulder, CO (US)

(72) Inventors: Scot Ronald Foss, Eden Prairie, MN (US); Samuel Ethan Messenger, Chaska, MN (US); Cory Robert Schwarting, Chaska, MN (US); Frederick Peter Alonzi, Bloomington, MN (US); Kyle Joseph McBrady, Maple Plain, MN (US)

(21) Appl. No.: 19/637,615

(22) Filed: Apr. 2, 2026

Related U.S. Application Data
(60) Provisional application No. 63/805,576, filed on May 14, 2025.

(51) Int. Cl. G01F 25/00; G01F 1/58; G01R 31/52

(52) U.S. Cl. CPC G01F 25/0092; G01F 1/584; G01F 1/586; G01R 31/52

(57) ABSTRACT

In one aspect, a magnetic flowmeter for measuring flow rate of a process fluid includes a flow tube arranged to receive a flow of the process fluid therethrough. A magnetic coil is arranged proximate the flow tube to apply a magnetic field to the process fluid flowing through the flow tube. A pair of electrodes are electrically coupled to the process fluid in the flow tube and arranged to sense a voltage induced in the process fluid related to the applied magnetic field and a flow rate of the process fluid. Transmitter circuitry receives the voltage sensed by the pair of electrodes. The transmitter circuitry includes drive circuitry configured to apply an electric current to the magnetic coil and verification circuitry that carries out redundant measurements of the electric current that flows through the magnetic coil and determines whether there is leakage of the electric current by comparing measurement values obtained from the redundant measurements. In another aspect, a magnetic flowmeter for measuring flow rate of a process fluid includes a flow tube arranged to receive a flow of the process fluid therethrough. A magnetic coil is arranged proximate the flow tube to apply a magnetic field to the process fluid flowing through the flow tube. A pair of electrodes are electrically coupled to the process fluid in the flow tube and arranged to sense a voltage induced in the process fluid related to the applied magnetic field and a flow rate of the process fluid. Transmitter circuitry receives the voltage sensed by the pair of electrodes. The transmitter circuitry includes drive circuitry configured to apply an electric current to the magnetic coil and verification circuitry that carries out measurements of an inductance of the coil that are invariant across at least one of a full coil current range, a range of coil drive frequencies or a range of coil drive voltages.

### CROSS-REFERENCE TO RELATED APPLICATION

The present application is based on and claims the benefit of U.S. provisional patent application Ser. No. 63/805,576, filed May 14, 2025, the content of which is hereby incorporated by reference in its entirety.

### BACKGROUND

Embodiments of the present disclosure relate to magnetic flowmeters and, more specifically, to diagnostics/calibration verification in such flowmeters.

Magnetic flowmeters (or mag meters) measure flow of process fluid by application of Faraday's Law, an electromagnetic effect. The magnetic flowmeter energizes one or more coils by passing an excitation current through field windings which generates a magnetic field across an electrically isolated, conductive process flow. An electromotive force (EMF) is generated by the flowing process fluid crossing through the magnetic field; this induced voltage (potential) both across the fluid and with respect to the rest of the process fluid can readily be measured by one or more conductive electrodes that contact the flowing process fluid. Alternatively, some magnetic flowmeters employ capacitive coupling between the electrodes and the process fluids such that the potential can be measured without direct electrical connection to the process. The volumetric flow is proportional to the flow velocity and the cross-sectional area of the flow tube. As the flow velocity is directly proportional to the electrode voltage potential (EV), the measured voltage can be used to determine flow rate.

Magnetic flowmeters are useful in a variety of conductive and semi-conductive fluid flow measurement environments. In particular, the flow of water-based fluids, ionic solutions and other conducting fluids can all be measured using magnetic flowmeters. Thus, magnetic flowmeters can be found in water treatment facilities, beverage and hygienic food production, chemical processing, high purity pharmaceutical manufacturing, as well as hazardous and corrosive processing facilities. Magnetic flowmeters are often employed in the hydrocarbon fuel industry, which sometimes employs hydraulic fracturing techniques using abrasive and corrosive slurries.

During the lifetime of a magnetic flowmeter, various components may completely fail, or electrical parameters of components may drift from their original, calibrated, values. This can lead to inaccurate flow measurements.

### SUMMARY

In one aspect, a magnetic flowmeter for measuring flow rate of a process fluid includes a flow tube arranged to receive a flow of the process fluid therethrough. A magnetic coil is arranged proximate the flow tube to apply a magnetic field to the process fluid flowing through the flow tube. A pair of electrodes are electrically coupled to the process fluid in the flow tube and arranged to sense a voltage induced in the process fluid related to the applied magnetic field and a flow rate of the process fluid. Transmitter circuitry receives the voltage sensed by the pair of electrodes. The transmitter circuitry includes drive circuitry configured to apply an electric current to the magnetic coil and verification circuitry that carries out redundant measurements of the electric current that flows through the magnetic coil and determines whether there is leakage of the electric current by comparing measurement values obtained from the redundant measurements.

In another aspect, a magnetic flowmeter for measuring flow rate of a process fluid includes a flow tube arranged to receive a flow of the process fluid therethrough. A magnetic coil is arranged proximate the flow tube to apply a magnetic field to the process fluid flowing through the flow tube. A pair of electrodes are electrically coupled to the process fluid in the flow tube and arranged to sense a voltage induced in the process fluid related to the applied magnetic field and a flow rate of the process fluid. Transmitter circuitry receives the voltage sensed by the pair of electrodes. The transmitter circuitry includes drive circuitry configured to apply an electric current to the magnetic coil and verification circuitry that carries out measurements of an inductance of the coil that are invariant across at least one of a full coil current range, a range of coil drive frequencies or a range of coil drive voltages.

This Summary is provided to introduce a selection of concepts in a simplified form that are further described below in the Detailed Description. This Summary is not intended to identify key features or essential features of the claimed subject matter, nor is it intended to be used as an aid in determining the scope of the claimed subject matter. The claimed subject matter is not limited to implementations that solve any or all disadvantages noted in the Background.

### BRIEF DESCRIPTION OF THE DRAWINGS

FIG. 1 illustrates a simplified diagram of a magnetic flowmeter system having verification circuitry according to an embodiment of the present disclosure.

FIG. 2 illustrates a magnetic flowmeter assembly in another example configuration including a magnetic flowmeter with a portion shown in cross-section.

FIG. 3 is a simplified block diagram of illustrating functional elements of a transmitter and magnetic flowmeter according to an embodiment of the present disclosure.

FIG. 4 is a simplified block diagram of verification circuitry according to an embodiment of the present disclosure.

FIG. 5 is a simplified diagram showing electrical impedance between electrodes in a flowmeter.

FIG. 6 is a simplified schematic diagram of impedance measurement circuitry according to an embodiment of the present disclosure.

FIG. 7 is a graph of coil current versus time.

FIG. 8 is a graph of measurement signal amplitude versus time.

FIG. 9 illustrates a portion of the flowmeter circuitry of FIG. 3 with shunt resistors included according to an embodiment of the present disclosure.

### DETAILED DESCRIPTION OF ILLUSTRATIVE EMBODIMENTS

Embodiments of the present disclosure are described more fully hereinafter with reference to the accompanying drawings. Elements that are identified using the same or similar reference characters refer to the same or similar elements. Some elements may not be shown in each of the figures in order to simplify the illustrations. The various embodiments of the present disclosure may be embodied in many different forms and should not be construed as limited to the specific embodiments set forth herein. Rather, these embodiments are provided so that this disclosure will be thorough and complete, and will fully convey the scope of the present disclosure to those skilled in the art.

Specific details are given in the following description to provide a thorough understanding of the embodiments. However, it is understood by those of ordinary skill in the art that the embodiments may be practiced without these specific details. For example, circuits, systems, networks, processes, frames, supports, connectors, motors, processors, and other components may not be shown, or shown in block diagram form, in order to avoid obscuring the embodiments in unnecessary detail.

Some industries require customers to verify the calibration of their magnetic flowmeters to within a certain percentage (e.g., 2%). There are several methods to achieve this:
1) External verification: remove the flow tube from the line and verify the calibration by sending it to the factory, a certified lab, or performing in-house tests with additional equipment (e.g., a prover or reference meter).
2) External device: use an expensive external device connected to the flowmeter sensor and transmitter, which verifies that the original characteristics of the sensor and transmitter have not changed significantly. This method typically requires a trained technician to run the test.
   These methods are time consuming and may require the process to be taken offline.

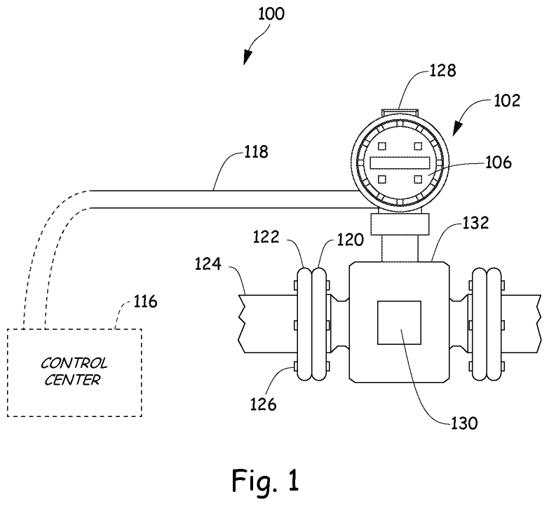

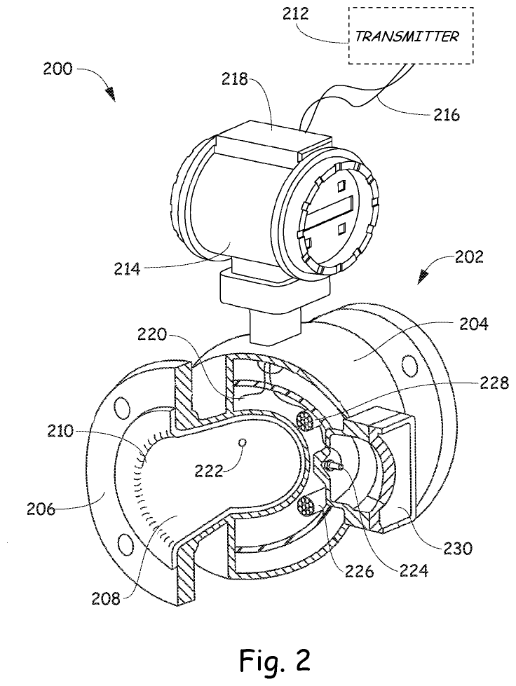

Embodiments of the disclosure provide an integrated verification system for magnetic flowmeters, which allows for flowmeter calibration verification without removing the flowmeter sensor or using external devices. In one aspect, verification circuitry is incorporated into the flowmeter transmitter and is capable of verifying the operation of the flowmeter in-situ while still measuring flow. This solution addresses the problem of maintaining accurate calibration. The verification circuitry of the transmitter measures key parameters such as voltage, inductance, capacitance or resistance, or other parameters to verify that the sensor and transmitter are still operating properly and at the specified accuracy. The measurements are calibrated at the factory, and the verification tests verify that the measurements have not changed. The verification tests may be performed on-demand, at periodic intervals, and continuously. Prior to providing details regarding verification techniques and features that help ensure measurement accuracy, example magnetic flowmeter assemblies are described below in connection with FIGS. 1 and 2.

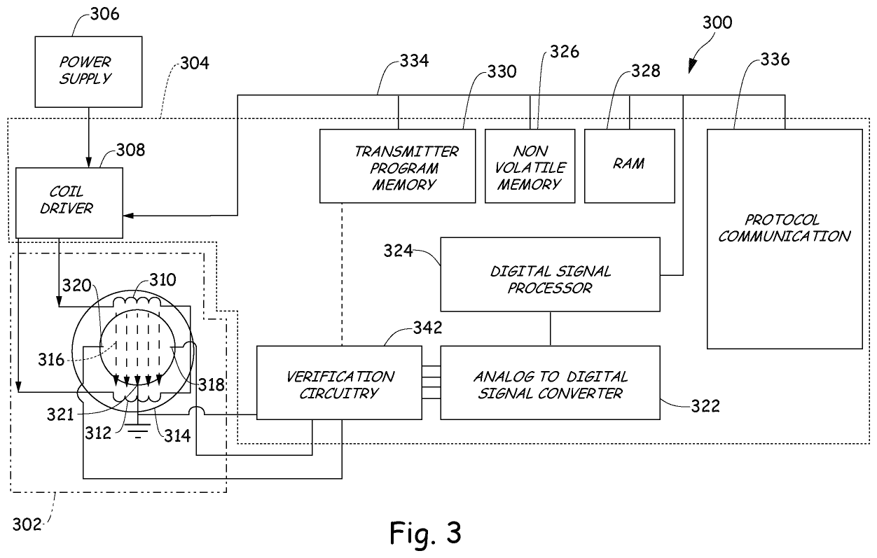

FIG. 1 illustrates a simplified diagram of a magnetic flowmeter assembly 100 having verification circuitry according to an embodiment of the present disclosure. Magnetic flowmeter assembly 100 includes a magnetic flowmeter 102. A process control loop 118 couples flowmeter 102 to a control center 116. This loop 118 can be a wired or wireless process control loop. The connection can be used for transmitting alarm signals, measurement data, and the like and for receiving control signals. Process electronics are generally housed within the flowmeter and can be electrically coupled to the local user interface 106. Parameters can also be provided to, or read from, flowmeter 102 over loop 118 as well as through a handheld communicator or the like. The process electronics may include verification circuitry (illustrated generally in FIG. 3) along with memory for storing baseline calibration values and raw flow measurement data, one or more microprocessors, and software (sometimes referred to as “firmware”).

Electrical interconnects and magnetic coils (shown in FIGS. 2 and 3) are confined within the flowmeter 102 and are isolated from the environment and from the process.

Generally, the magnetic flowmeter 102 is coupled to pipe section 124 by flanges 120 and corresponding pipe flanges 122 using threaded fasteners 126. Though FIG. 1 illustrates a pipe section 124, which is a tube, the flowmeter 102 can be coupled to other types of fluid conveying structures as well. As used herein, the term “pipe” refers generally to any conduit for conveying fluid, including a tube, a channel, and the like.

Finally, access panel 128 may be provided to allow an operator access to the electrical interconnections for coupling the process electronics within the flowmeter 102 to the process control loop 118. Additionally, in some embodiments, access panel 130 may be provided to permit operator access to electrode wiring within the flowmeter body 132.

FIG. 2 illustrates a magnetic flowmeter assembly 200 in another example configuration including a magnetic flowmeter 202 with a portion shown in cross-section. The magnetic flowmeter 202 includes a pipe section 204 with flanges 206 for coupling to a pipe or conduit of an industrial process. The pipe section 204 defines a passage 208 for fluid flow. Generally, the pipe section 204 is formed of a rigid material, such as nonmagnetic stainless steel for pressure containment, and may be lined with an electrically insulating liner 210, such as Teflon, polyurethane, Tefzel, other plastic resin, ceramic, or other types of electrically insulating materials. For lower pressure applications, pipe section 204 can be formed from electrically insulative material, in which case liner 210 may be omitted. Other designs of passages 208 can be used as well. For example, a metal pipe section can be used having only a partial insulating lining such as an insulating annulus about each electrode.

Additionally, though the flowmeter 202 is shown with flange elements 206, other connection means are possible. In an alternative embodiment, the pipe section 204 can be formed without flanges, and the flowmeter 202 can be clamped between flanges of mating pipes using extended bolts to cage the flowmeter 202.

In one embodiment, a transmitter is included internal to electronics housing 214 of the flowmeter 202. In an alternate embodiment, the transmitter may be located external to the electronics housing. Such an external or remote transmitter is labeled 212 in FIG. 2 and is coupled to the electronics housing 214 of the flowmeter 202 via wiring 216. The electronics housing 214 is provided with a releasable cover 218 to allow operator access to an electrical distribution block and electrical connectors provided within the electronics housing 214.

In general, any suitable electrical coupling may be used to electrically connect sensor elements to electronics the housing 21. The electrical coupling may be via an interconnect or by electrical leads 220 that extend from within the electronics housing 214 into the pipe section 204 to connect to electrodes 222 and 224 and to magnetic coils 226 and 228. Finally, access panel 230 may be provided to allow operator access to wiring within the pipe section 204.

The magnetic coils 226 and 228 are excited to generate a magnetic field, which induces a voltage in the process fluid flow within the pipe section 204. In one embodiment, the electronics within the electronics housing 214 measures the voltage potential between the two electrodes 222 and 224, which can be used to determine a rate of flow. Specifically, the magnitude of the induced voltage (E) is directly proportional to the velocity of the conducting fluid (V), the conductor width (W), and the strength of the magnetic field (B) according to the following equation: E=kBWV where the variable k represents a constant. The magnetic field coils 226 and 228 are generally positioned on opposing sides of the pipe section 204 to generate the field. As the conductive liquid moves through the field with average velocity (V), the electronics measures the voltage potential across electrodes 222 and 224. Alternatively, the electronics can be configured to measure a voltage potential relative to ground or relative to a process reference. In one embodiment, the process reference is a fixed potential.

Since the width (W) is the spacing between the electrodes and the magnetic field (B) is controlled by the magnetic coils 226 and 228, the only variable is the velocity (V) of the process fluid. The liner 210 (or an insulating element) prevents the voltage signal from shorting to the pipe wall. Thus, the output voltage (E) is directly proportional to the liquid velocity, resulting in an inherently linear output. This output voltage (E) may also be referred to as an “electromotive force” (EMF), a “flow signal”, a “potential” or an “electrode voltage”. It should be understood that electrodes 222 and 224 contact the fluid in the passage 208 (when liquid is present), and the fluid completes a circuit between the electrodes 222 and 224.

FIG. 3 is a simplified block diagram of a magnetic flowmeter assembly 300 illustrating some of the functional elements of a transmitter according to an embodiment of the present disclosure. The assembly 300 includes a flowmeter sensor 302, which is coupled to transmitter 304 via an electrical connection.

The flowmeter sensor 302 receives power from a power supply 306 (such as the loop wiring or other power supply). The power received by the flowmeter sensor 302 drives the coil driver 308, which powers the magnetic coils 310 and 312 disposed on opposing sides of the flow pipe 314 to generate a magnetic field 316 through the flow pipe 314. The drive signal is typically a square wave such that the direction of electric current through the coils 310, 312 periodically reverses direction. Electrodes 318 and 320 sense the induced voltage due to the applied magnetic field and flow of process fluid, which is processed by an analog to digital signal converter 322. This conversion allows for precise corrections and engineering unit conversion. Digital signal processor (DSP) or microprocessor 324 receives the converted digital signal from converter 322. The DSP 324 can perform various processing steps on the data and on the flowmeter sensor 302, including diagnostics, signal processing, electronics and tube calibrations, and the like. A ground electrode 321 is also provided for coupling to process ground. Verification circuitry 342 is also coupled to electrodes 318, 320 to carry out calibration verification functions as discussed herein. Verification circuitry 342 can also optionally couple to ground electrode 321.

Configuration data for the assembly 300 may be stored in first non-volatile memory 326. The first non-volatile memory 326, RAM 328, and second non-volatile memory 330 (which stores the transmitter firmware) are connected to the microprocessor 324 via bus 334. In general, any suitable number and types of memories may be included in the transmitter 304. Depending on the specific implementation, the transmitter 304 may be adapted to produce various outputs via one or more different communication protocols. Accordingly, protocol communication 336 can include, but is not limited to, Fieldbus, Modbus, HART, among other protocols. Any suitable I/O circuitry may be employed in accordance with the implementation.

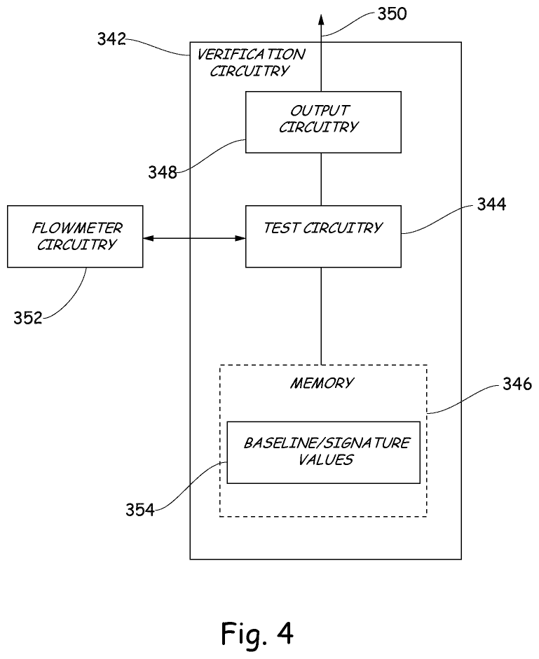

FIG. 4 is a simplified block diagram of verification circuitry 342. Verification circuitry 342 includes test circuitry 344, memory 346 and output circuitry 348. Output circuitry 348 is configured to provide the output 350. The various elements which comprise verification circuitry 342 may be embodied in other elements of flowmeter assembly 300. For example, the memory 346 may be shared with other components (e.g., one or more of memories 326, 328 and 330) of flowmeter assembly 300. Similarly, the test circuitry 344 may be formed by discreet components, or may be shared with other components of flowmeter assembly 300, for example microprocessor 324, analog to digital converter 322, sensors, amplifiers, etc. The output circuitry 348 may be output circuitry which is independent from other circuitry from within flowmeter assembly 300, or may be shared with other circuitry within the flowmeter assembly 300.

The test circuitry 344 is shown as interfacing with flowmeter circuitry 352. Flowmeter circuitry 352 may be any of the circuitry used in flowmeter assembly 300.

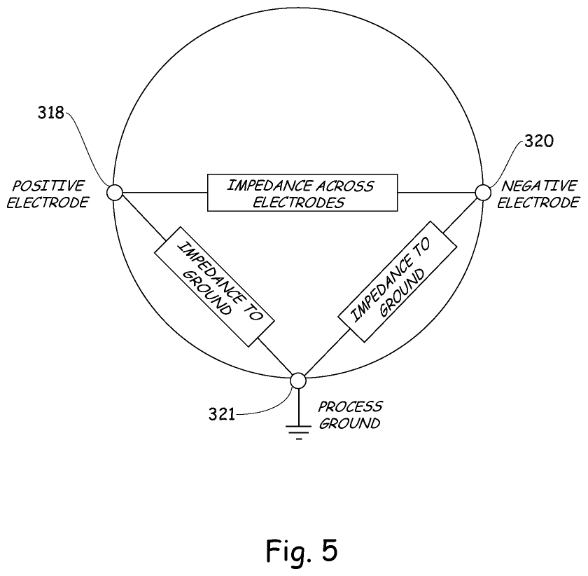

During operation, test circuitry 344 performs one or more tests on flowmeter circuitry 352. It should be noted that these tests are performed in situ and the flowmeter does not need to be removed from service. The results of the tests are compared with one or more baseline or signature values 354 stored in memory 346. As noted above, the memory 346 may be shared with other components such as memories 326, 328 and 330. Accordingly, in one embodiment, memory 330 stores the baseline or signature values 354 and the results of the tests are compared with one or more of the values 354 stored in the memory 330. The connection between the verification circuitry 342, which includes the test circuitry 344, and the memory 330 is represented by the dashed line connecting these two components in FIG. 3. In another embodiment, the baseline or signature values may be stored in memory 326 and the verification circuitry 342 may compare test results with baseline values stored in that memory. The baseline values may be specific values, values with a percent range, a range of values, or other way of identifying acceptable result from the test performed on the flowmeter circuitry 352. Based upon the comparisons, an output is provided from verification circuitry 342 by output circuitry 348. Examples of transmitter and sensor tests are listed below and described in detail further below in connection with FIGS. 5 through 9.

In one aspect, the verification circuitry 342 verifies that the transmitter 304 of flowmeter assembly 300 can measure flow accurately and that the output provided by the transmitter 304 is an accurate representation of the flow value. The measurements may be calibrated at the factory, and the verification tests verify that they have not changed. The verification may be through a number of techniques, including:
1) Analog output verification—an independent current measurement is performed by verification circuitry 342 to verify the 4-20 mA output.
2) Internal flow simulator—a signal is injected onto the electrode measurement circuity by verification circuitry 342. This signal is calibrated at the factory to verify that the electrical components have not drifted or failed. Details regarding the internal flow simulator and noise rejection when carrying out internal flow simulation are described further below.
3) Coil current—redundant coil current measurements are carried out by the verification circuitry 342 to verify that the coil current is accurate and has not drifted over time. Details regarding such measurements are provided further below.
4) Coil current ADC (analog to digital converter) reference—a reference voltage is fed into the coil current measurement ADC by the verification circuitry 342 to verify that the measurement is accurate.

In another aspect, the verification circuitry 342 of the transmitter 304 ensures the integrity of various components of the sensor 302 by verifying that they have not changed. This may be carried out by comparing values measured in the field to baseline or signature values established during factory calibration or from a known adequately-performing installation. The values that may be verified include the following:
1) Coil inductance—the coil inductance is measured because it represents the gain of the sensor. The coils produce the magnetic field that induces the electrode voltage. This is directly related to the gain of the sensor.
2) Coil resistance—the coil resistance is a measurement of the coil circuit health.
3) Electrode impedance—electrode resistance measurements are utilized to detect whether the electrodes are still connected to the process and that the process ground is intact. Multiple configurations and frequencies may be utilized to obtain complete diagnostics of the electrodes and process fluid coupling.
4) Electrode impedance ratio—this includes a ratio of the impedance between the flow sensing electrodes and the flow sensing electrodes to process ground at the end of the sensor or a ground electrode. This information may be taken at the factory and compared in the field. This ratio is independent of the conductivity of the fluid and can indicate several abnormal conditions, such as an electrode leak.

It should be noted that measured values for each of the above-listed characteristics may be stored in non-volatile memory in the transmitter 304 before the magnetic flowmeter 300 is put into service. The values stored in the non-volatile memory are baseline parameters. The baseline parameters of the sensor characteristics are compared with values measured by the verification circuitry 342 of the transmitter 304 to verify that the sensor 302 calibration has not shifted. The baseline parameters can be derived in several ways, for example:
1) Measured at the factory
2) Measured via external equipment such as a high current LCR meter, which measures inductance (L), capacitance (C) and resistance (R), and an ohmmeter.
3) Measured with the transmitter of the flowmeter, for example, as part of the installation procedure.

FIG. 5 is a simplified diagram showing electrical impedance between electrodes in a flowmeter. In embodiments of the disclosure, measurement circuitry 342 of flowmeter assembly 300 can measure the AC impedance between all three process fluid connections 318, 320 and 321 in the sensor. In general, the functionality of an LCR meter is incorporated into the transmitter electronics of flowmeter 300. The AC impedance measurements are taken at multiple frequencies to identify potential faults. The measurements are carried out in a manner that does not interfere with the flow measurement.

In one embodiment, in order to measure the impedance between two electrodes, a sine wave (impedance measurement signal) is injected through resistors across the electrodes and measurement circuitry to create a voltage divider. The voltage output is measured, and AC circuit analysis is used to solve for a parallel RC model of the electrode complex impedance. The coil drive signal is typically a square wave that causes current through the coils 310, 312 to periodically reverse direction and generates the applied magnetic field. This causes a measurement signal to be sensed by electrodes 318, 320 which is also a square wave at the same frequency having an amplitude which is related to flow rate. In one aspect, the sine wave impedance measurement signal is injected during a specific time in the period of the magnetic coil drive signal. For example, the impedance measurement signal can be injected during a period in which flow is not being measured. Specifically, during the period that the measurement circuitry waits for the flow measurement signal to settle and stabilize following a reversal of the applied magnetic field.

As indicated above, the impedance measurement signal may be applied at different frequencies to collect additional information. The different frequency signals may be applied simultaneously or sequentially, or a combination of both.

Additionally, in one configuration, the applied impedance measurement signal has a frequency which is an even harmonic of the coil drive frequencies. This guarantees that the flow measurement signal will not be affected by the impedance drive signal. The impedance measurement signal frequency is automatically adjusted to account for line noise harmonics and the harmonics of the flow signal.

The impedance measurement signal amplitude is continually adjusted to ensure that the signal is large enough to obtain an accurate measurement, but not too large to saturate the analog to digital convertor 322 and the measured impedance changes.

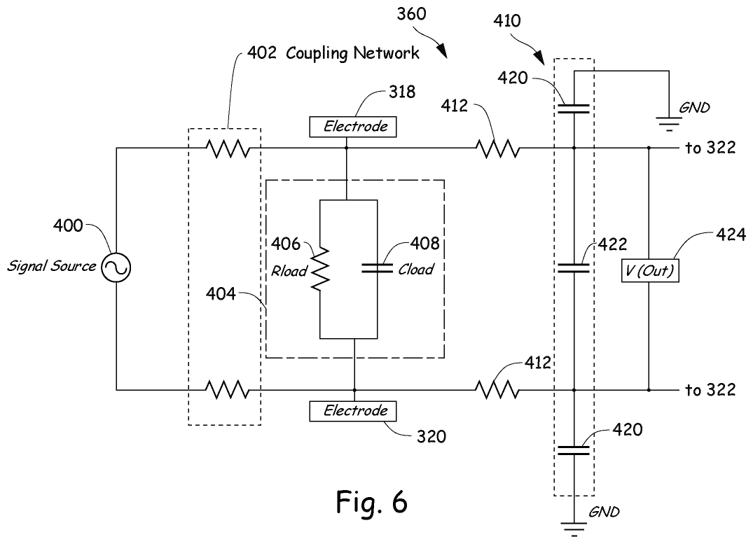

FIG. 6 is a simplified schematic diagram of impedance measurement circuitry 360 that may be a part of verification circuitry 342 according to one embodiment. The impedance measurement circuitry 360 includes a signal source 400 which injects the impedance measurement signal into the electrodes 318, 320 through coupling network 402. In one specific example, network 402 is formed by series connected resistors. The signal source 400 can be a voltage or current source. The impedance 404 between electrodes 318 and 320 is illustrated by a load resistor R_{load} 406 and a load capacitor C_{load} 408. Electrodes 318 and 320 are also connected to a capacitor network 410 through resistors 412 which are 12.4 K Ohm resistors in this example. A capacitor bank 410 is formed by capacitors 420 which connect the resistors 412 to electrical ground. Capacitor 422 is electrically connected between resistors 412. In one configuration, capacitors 420 are 39 pF and capacitor 422 has a capacitance of 330 pF. This configuration generates an output Vₒᵤₜ 424 which is the measurement signal generated by the flow of the process fluid in the applied magnetic fields and filters out the impedance measurement signal. Further, the measurement output signal 424 is also coupled to analog to digital convertor 322 for measurement of flow rate.

The electrodes 318 and 320 are connected to analog to digital convertor 322 through verification circuitry 342 for measuring a response of the applied impedance measurement signal. The magnitude and phase of the response of the electrodes 318, 320 to the applied impedance measurement signal can be measured using spectrum analysis or other means. The simplified circuit model illustrated at 404 can be solved to determine the impedance (R_{load} and C_{load}) across the electrodes 318, 320. The resistance 406 in this model is not affected by cabling capacitance and other parasitic components.

It should be noted that although FIG. 6 indicates that the impedance measurement is carried out across the electrodes 318, 320, in the configuration of FIG. 6, the electrodes can be any of the positive, negative or ground electrodes.

In embodiments of the disclosure, impedance measurements carried out by the verification circuitry 342 include the following:
Positive electrode to negative electrode
Positive electrode to process ground
Negative electrode to process ground
Common mode (same signal on both electrodes) to process ground

It should be noted that the process ground can be in the form of a metal pipe, ground rings, liner protectors, a dedicated electrode, or other electrical connection.

As indicated earlier, verification circuitry 342 determines electrode impedance ratios. Accordingly, after obtaining the above-described electrode impedance measurements, verification circuitry 342 computes a ratio of the impedance between the flow sensing electrodes and the flow sensing electrodes to process ground. This information may be taken at the factory and stored in non-volatile memory 346 as part of baseline/signature values 354 and later compared with measurement data and ratios obtained and computed in the field. As noted earlier, this ratio is independent of the conductivity of the fluid and can indicate several abnormal conditions, such as an electrode leak.

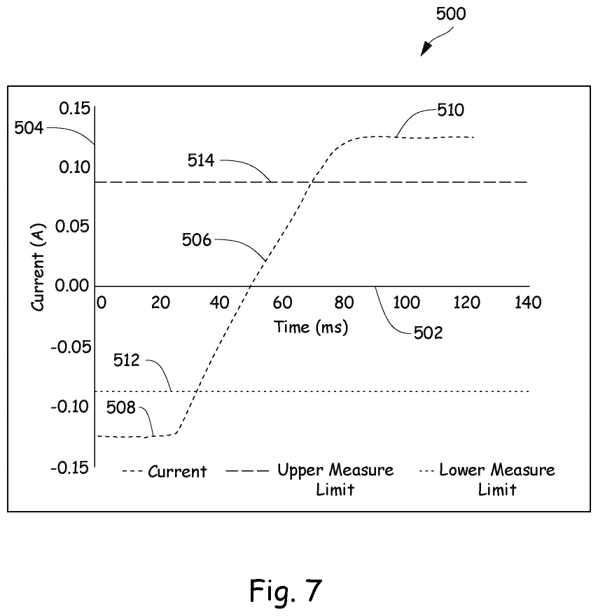

In general, a magnetic flowmeter can calculate coil inductance directly from the applied voltage and coil current. In high-temperature processes, the flowmeter transmitter reduces coil current to conserve power. However, because materials in the magnetic circuit may exhibit nonlinear magnetic properties, the coil inductance can vary with current. This variation could lead to inaccurate inductance calculations, potentially confusing users or causing failures in diagnostics. To address this problem, in one aspect, the transmitter compensates for current-dependent inductance changes. Such compensation is described below in connection with FIG. 7.

FIG. 7 is a graph 500 of coil current versus time. In FIG. 7, horizontal axis 502 represents time in milliseconds (ms) and vertical axis 504 represents current in amperes (A). Graph 500 illustrates a coil current waveform 506 that has a low level 508 and a high level 510. During, for example, a coil inductance baseline value determination procedure, the transmitter 304 (or, more specifically, the verification circuitry 342 of transmitter 304) measures inductance at both low 508 and high 510 coil current levels. With these two reference points, the transmitter 304 linearly scales inductance across the full operating current range. This ensures that any variation in coil current is accounted for, thereby maintaining a consistent and accurate coil inductance value.

In addition to current compensation, the inductance calculation method itself is enhanced. Traditional methods often use the entire coil current waveform, which includes periods where there are inconsistent rates of changes to the coil current. These inconsistencies can introduce an unreliable coil inductance measurement.

In embodiments of the disclosure, the transmitter 304 (or, more specifically, the verification circuitry 342 of the transmitter 304) improves accuracy by analyzing only a portion of the waveform—for example, the middle 70% of each waveform cycle between a lower measurement limit 512 and an upper measurement limit 514—where the current is most stable. By focusing on this steady-state portion, the transmitter 304 delivers a more reliable and precise inductance calculation.

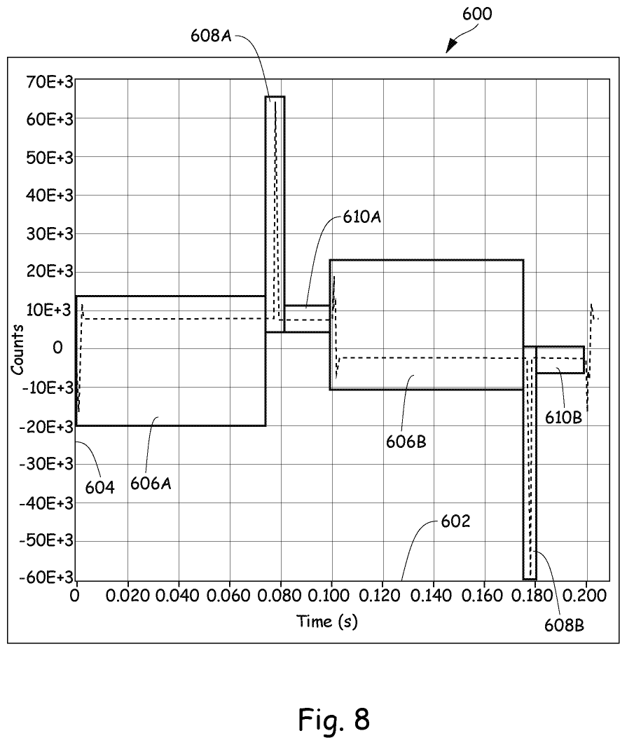

In addition to the improvements in measurements and calculations described above, embodiments of the disclosure also refine an internal flow simulator (IFS) signal, which is a fixed known measurement based on physical hardware design and is measured using the same or similar circuitry as the electrode voltage. This allows the transmitter to verify that the hardware is free of any changes that could affect its performance and accuracy. As this measurement can be susceptible to noise from the surroundings and the process slurry, additional precautions can be taken to mitigate or reject such interference that may corrupt the IFS measurement. In general, embodiments of the disclosure may employ one or more noise mitigation/rejection features (e.g., filters, averaging of IFS measurements, etc.) in the transmitter. Examples of some such features are described below in connection with FIG. 8.

FIG. 8 is a graph 600 of measurement signal amplitude versus time. In FIG. 8, horizontal axis 602 represents time in seconds(s) and vertical axis 604 represents amplitude in counts. Graph 600 shows coil stabilization durations 606A and 606B, IFS measurement durations 608A and 608B and flow measurement durations 610A and 610B. A first precaution is to limit the amount of noise that corrupts the IFS measurement. This is carried out by employing a fast measurement time of the IFS injected signal and measuring for only a predetermined short duration, such as for 128 microseconds. Examples of such short durations are 608A and 608B shown in FIG. 8. A second precaution is to take the average of positive and negative IFS measurements to reduce or minimize any electronic component differences. Another precaution is to place a filter, such as a Hampel filter, on the IFS measurement to reject spike or impulse noise caused by slurry particles impacting the electrodes. For example, this filter can be configured to reject noisy samples beyond 2 standard deviations of a 39-sample filter. In one embodiment, the noise-rejection filter (e.g., the Hampel filter) may be stored as firmware in non-volatile memory 346 of verification circuitry 342 and executed by digital signal processor 324. The IFS signal injection and subsequent measurements and verification may be carried out by test circuitry 344 of the verification circuitry 342. A zero offset IFS measurement may also be carried out by the verification circuitry 342. Here, the verification circuitry 342 performs an IFS measurement without any signal to be subtracted from the IFS value. An IFS test may be run by verification circuitry 342 without a signal and the resulting IFS value indicative of noise may be measured by the verification circuitry 342.

The combination of these above-described improvements helps reject noisy samples in the flowmeter verification due to a noisy process or its ambient settings. This directly helps limit the number of false positive failures in the IFS diagnostic. Under the circumstances of a true positive failure, where the hardware has shifted over time, the user is able to perform a digital trim routine to calibrate the flow measurement to correct for errors which arise due to this failure. This method can use an external calibrator to adjust both the flow measurement, as well as the internal flow simulator, back to a known suitable value, allowing the device to continue operating in the field.

In embodiments of the disclosure, redundant coil current measurements are also carried out. In this aspect, flowmeter circuitry such as verification circuitry 342 carries out redundant measurements of the electric current that flows through the magnetic coil and determines whether there is leakage of the electric current by comparing measurement values of the electric current obtained from the redundant measurements.

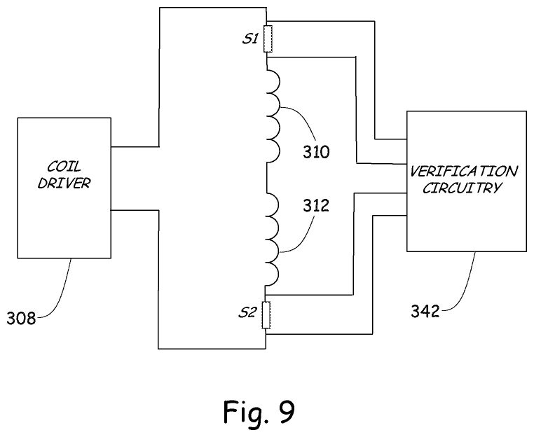

FIG. 9 illustrates a portion of the flowmeter circuitry of FIG. 3 with shunt resistors S1 and S2 included for use in measuring current entering and exiting the coils 310 and 312, respectively, which are powered by coil driver 308. Verification circuitry 342 is connected to measure respective voltage drops across shunt resistors S1 and S2, which have known values. Verification circuitry 342 can compute the electric current entering the coils 310 and 312 by measuring the voltage across the first shunt resistor S1 and dividing it by the know resistance value of S1. Similarly, verification circuitry 342 computes the electric current leaving the coils 310 and 312 by measuring the voltage across the second shunt resistor S2 and dividing it by the know resistance value of S2. Both of these measurements are compared to ensure that the system is operating properly. This ensures that the entire sensor is being properly driven, with no current leakage that would induce an inaccurate flow signal. If a coil current failure is detected, the user is alerted and can perform a digital trim routine which will trim the coil current resistors back together using an external calibrator.

Although the present invention has been described with reference to preferred embodiments, workers skilled in the art will recognize that changes may be made in form and detail without departing from the spirit and scope of the invention.

What is claimed is:

1. A magnetic flowmeter for measuring flow rate of a process fluid, comprising:
a flow tube arranged to receive a flow of the process fluid therethrough;
a magnetic coil arranged proximate the flow tube to apply a magnetic field to the process fluid flowing through the flow tube;
a pair of electrodes electrically coupled to the process fluid in the flow tube and arranged to sense a voltage induced in the process fluid related to the applied magnetic field and a flow rate of the process fluid; and
transmitter circuitry configured to receive the voltage sensed by the pair of electrodes, the transmitter circuitry comprising:
drive circuitry configured to apply an electric current to the magnetic coil; and
verification circuitry configured to carry out redundant measurements of the electric current that flows through the magnetic coil and to determine whether there is leakage of the electric current by comparing measurement values obtained from the redundant measurements.

2. The magnetic flowmeter of claim 1 and further comprising a first shunt resistor in a first branch of the drive circuitry through which the electric current enters the magnetic coil, and a second shunt resistor in a second branch of the drive circuitry through which the electric current leaves the magnetic coil.

3. The magnetic flowmeter of claim 2, wherein the verification circuitry is electrically connected across the first and second shunt resistors, and wherein the verification circuitry is configured to compare a first measurement value of the electric current obtained via the first shunt resistor with a second measurement value of the electric current obtained via the second shunt resistor and to thereby determine whether there is leakage of the electric current.

4. The magnetic flowmeter of claim 1, wherein the transmitter circuitry further comprises a non-volatile memory configured to store a plurality of baseline flowmeter parameter values, and wherein the verification circuitry is configured to measure flowmeter parameter values during operation of the magnetic flowmeter in-situ, compare the baseline flowmeter parameter values with the measured flowmeter parameter values, and thereby verify whether the magnetic flowmeter is operating at a predetermined accuracy.

5. The magnetic flowmeter of claim 4, wherein the verification circuitry is further configured to:
determine an impedance value across the pair of electrodes; and
compare the determined impedance value with a baseline electrode impedance value stored in the non-volatile memory.

6. The magnetic flowmeter of claim 4, wherein the verification circuitry is further configured to:
calculate a first impedance across the pair of electrodes;
calculate second impedances of:
a first electrode of the pair of electrodes to process ground,
a second electrode of the pair of electrodes to the process ground; and
a common mode, with a same signal on both the first and second electrodes, to process ground;
determine ratios of the first impedance to each of the second impedances; and
compare the ratios with corresponding ratios stored in the non-volatile memory.

7. The magnetic flowmeter of claim 1, wherein the verification circuitry is further configured to carry out internal flow simulator (IFS) diagnostics and to reject noise from IFS measurements performed during the IFS diagnostics.

8. The magnetic flowmeter of claim 7, wherein the IFS measurements include a zero offset measurement.

9. The magnetic flowmeter of claim 7, wherein the verification circuitry is configured to reject noise from the IFS measurements by limiting an IFS signal injection and measurement time to a predetermined short duration.

10. The magnetic flowmeter of claim 7, wherein the verification circuitry is configured to reject noise from the IFS measurements by averaging positive and negative IFS measurement values.

11. The magnetic flowmeter of claim 7, wherein the verification circuitry is configured to reject noise from the IFS measurements by placing a Hampel filter on the IFS measurements, and wherein the Hampel filter is configured to reject spike or impulse noise from the IFS measurements.

12. The magnetic flowmeter of claim 1, wherein the electric current applied to the magnetic coil comprises a pulse current, and wherein the verification circuitry is configured to determine a first inductance measurement value of the magnetic coil at a low level of the pulse current and a second inductance measurement value at a high level of the pulse current and, with the first and second inductance measurement values, linearly scale an inductance of the magnetic coil across a full operating current range.

13. The magnetic flowmeter of claim 1, wherein the electric current applied to the magnetic coil comprises a pulse current, and wherein the verification circuitry is configured to calculate an inductance of the magnetic coil by analyzing a predetermined middle portion of a waveform cycle of the pulse current.

14. A magnetic flowmeter for measuring flow rate of a process fluid, comprising:
a flow tube arranged to receive a flow of the process fluid therethrough;
a magnetic coil arranged proximate the flow tube to apply a magnetic field to the process fluid flowing through the flow tube;
a pair of electrodes electrically coupled to the process fluid in the flow tube and arranged to sense a voltage induced in the process fluid related to the applied magnetic field and a flow rate of the process fluid; and
transmitter circuitry configured to receive the voltage sensed by the pair of electrodes, the transmitter circuitry comprising:
drive circuitry configured to apply an electric current to the magnetic coil; and
verification circuitry configured to carry out internal flow simulator (IFS) diagnostics and to reject noise from IFS measurements performed during the IFS diagnostics.

15. The magnetic flowmeter of claim 14, wherein the verification circuitry is configured to reject noise from the IFS measurements by placing a Hampel filter on the IFS measurements, and wherein the Hampel filter is configured to reject spike or impulse noise from the IFS measurements.

16. The magnetic flowmeter of claim 14, wherein the verification circuitry is configured to reject noise from the IFS measurements by limiting an IFS signal injection and measurement time to a predetermined short duration.

17. The magnetic flowmeter of claim 14, wherein the verification circuitry is configured to reject noise from the IFS measurements by averaging positive and negative IFS measurement values.

18. The magnetic flowmeter of claim 14, wherein the IFS measurements include a zero offset measurement.

19. The magnetic flowmeter of claim 14, wherein the transmitter circuitry further comprises a non-volatile memory configured to store a plurality of baseline flowmeter parameter values, and wherein the verification circuitry is configured to measure flowmeter parameter values during operation of the magnetic flowmeter in-situ, compare the baseline flowmeter parameter values with the measured flowmeter parameter values, and thereby verify whether the magnetic flowmeter is operating at a predetermined accuracy.

20. A magnetic flowmeter for measuring flow rate of a process fluid, comprising:
a flow tube arranged to receive a flow of the process fluid therethrough;
a magnetic coil arranged proximate the flow tube to apply a magnetic field to the process fluid flowing through the flow tube;
a pair of electrodes electrically coupled to the process fluid in the flow tube and arranged to sense a voltage induced in the process fluid related to the applied magnetic field and a flow rate of the process fluid; and
transmitter circuitry configured to receive the voltage sensed by the pair of electrodes, the transmitter circuitry comprising:
drive circuitry configured to apply an electric current to the magnetic coil; and
verification circuitry configured to carry out measurements of an inductance of the coil that are invariant across at least one of a full coil current range, a range of coil drive frequencies or a range of coil drive voltages.

21. The magnetic flowmeter of claim 20, wherein the electric current applied to the magnetic coil comprises a pulse current, and wherein the verification circuitry is configured to determine a first inductance measurement value of the magnetic coil at a low level of the pulse current and a second inductance measurement value at a high level of the pulse current and, with the first and second inductance measurement values, linearly scale the inductance of the magnetic coil across a full operating current range.

22. The magnetic flowmeter of claim 20, wherein the electric current applied to the magnetic coil comprises a pulse current, and wherein the verification circuitry is configured to calculate the inductance of the magnetic coil by analyzing a predetermined middle portion of a waveform cycle of the pulse current.

23. The magnetic flowmeter of claim 20, wherein the transmitter circuitry further comprises a non-volatile memory configured to store a plurality of baseline flowmeter parameter values, and wherein the verification circuitry is configured to measure flowmeter parameter values during operation of the magnetic flowmeter in-situ, compare the baseline flowmeter parameter values with the measured flowmeter parameter values, and thereby verify whether the magnetic flowmeter is operating at a predetermined accuracy.
